(19) United States
(12) Patent Application Publication
(10) Pub. No.: US 2007/0007570 A1
(43) Pub. Date: Jan. 11, 2007

(54) Semiconductor device

(76) Inventor: Tetsuya Takahashi, Niiza-shi (JP)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(21) Appl. No.: 11/483,238

(22) Filed: Jul. 7, 2006

(30) Foreign Application Priority Data
Jul. 8, 2005 (JP) 2005-199758

(51) Int. Cl. H01L 29/94

(52) U.S. Cl. 257/302

(57) ABSTRACT

A semiconductor device has an N type diffusion layer between an insulating layer formed on the surface of a trench and an N type semiconductor region. An N type impurity is diffused in the N type diffusion layer so as to have a concentration gradient in a direction that connects a source electrode and a drain electrode. By having the N type diffusion layer, the semiconductor device can have a favorable depletion layer produced therein when a reverse-direction voltage is applied, and can reduce leak current. Thus, the semiconductor device has a favorable voltage withstand characteristic.

### BACKGROUND OF THE INVENTION

1. Field of the Invention

The present invention relates to a semiconductor device having a trench structure.

2. Description of the Related Art

A semiconductor device in which a trench is formed in its semiconductor base and a field plate is formed in the trench, is disclosed (Unexamined Japanese Patent Application KOKAI Publication NO. 2003-8006). This semiconductor device can prevent an electric field concentration therein.

FIG. 5 exemplarily shows a conventional semiconductor device 80 having a trench structure. The semiconductor device 80 comprises an N type semiconductor region 81, an N type drain region 82, a P type base region 83, an N type source region 84, an insulating layer 85, a field plate 86, a trench 90, a source electrode 91, a drain electrode 92, a gate electrode 93, and a gate insulating film 94.

When the electric potential of the drain electrode 92 is set higher than the electric potential of the source electrode 91, a depletion layer is produced near the interface between the P type base region 83 and the N type semiconductor region 81. Since the source electrode 91 and the field plate 86 contact each other in the semiconductor device 80, a depletion layer is also produced near the interface between the insulating layer 85 and the N type semiconductor region 81.

When the electric potential of the drain electrode 92 with respect to the electric potential of the source electrode 91 is raised further, a P type inversion layer 88 is produced near the interface between the N type semiconductor region 81 and the insulating layer 85 as shown in FIG. 6. The P type inversion layer 88 is produced inside the N type semiconductor region 81. The carrier concentration in the P type inversion layer 88 is higher where closer to the drain electrode 92 and lower where closer to the source electrode 91. The P type inversion layer 88 having this concentration gradient in its carrier concentration brings about the following problem. That is, in a case where a leak current flows in the P type inversion layer 88 in the Y direction (a direction heading from the drain electrode 92 to the source electrode 91), no favorable depletion layer will be produced in the N type semiconductor region 81. This gives birth to a problem that the semiconductor device 80 cannot achieve a fine voltage withstand characteristic.

Generally, the following method is employed in order to improve the voltage withstand characteristic of the semiconductor device 80. This method is to improve the voltage withstand characteristic by increasing the thickness of the insulating layer 85. However, there is a structural limit in increasing the thickness of the insulating layer 85. Furthermore, in a case where the insulating layer 85 is formed by thermal oxidation, another problem arises. That is, it is necessary to increase the manufacturing time to increase the thickness of the insulating layer 85, and the yield will be worsened if the manufacturing time is increased. As another method for increasing the voltage withstand characteristic of the semiconductor device 80, it is also conceivable to form the type semiconductor region 81 thick. However, if the N type semiconductor region 81 is formed thick, there will occur a problem that the on state voltage of the semiconductor device 80 is deteriorated.

### SUMMARY OF THE INVENTION

The present invention was made in view of the above-described circumstances. An object of the present invention is to provide a semiconductor device which can have its insulating layer and N type semiconductor region be as thin as conventional, and which has a favorable voltage withstand characteristic.

To achieve the above object, a semiconductor device according to a first aspect of the present invention comprises:

i. a semiconductor base comprising: a first semiconductor region having a first conductivity type; a second semiconductor region having a second conductivity type formed in a surface region of the first semiconductor region; a trench formed so as to extend from a surface region of the second semiconductor region into the first semiconductor region; an insulating layer formed on a surface of the trench, and a field plate formed so as to fill the trench via the insulating layer;

a first electrode formed on the second semiconductor region which is formed in one principal surface of the semiconductor base, such that the first electrode contacts the field plate; and

a second electrode formed on the other principal surface of the semiconductor base,

wherein the semiconductor device further comprises a diffusion layer in which an impurity is diffused with a concentration gradient running from a side of the first electrode to a side of the second electrode, in the first semiconductor region contacting the insulating layer in a direction connecting the first electrode and the second electrode.

The diffusion layer may be formed so as to include an inversion layer having an inverted conductivity type, which is produced in a region in the first semiconductor region that contacts the insulating layer, when a reverse-direction voltage is applied to the first electrode and the second electrode.

The diffusion layer may comprise a first region in which an impurity concentration is constant, and a second region in which an impurity concentration is higher than that in the first region;

the first region and the second region may be arranged alternately; and

an average of the impurity concentration in the first region and the impurity concentration in the second region adjoining the first region may decrease from the side of the second electrode to the side of the first electrode.

The diffusion layer may be formed so as to include an inversion layer having an inverted conductivity type, which is produced in a region in the first semiconductor region that contacts the insulating layer, when a reverse-direction voltage is applied to the first electrode and the second electrode;

the diffusion layer may comprise a first region in which an impurity concentration is constant, and a second region in which an impurity concentration is higher than that in the first region;

the first region and the second region may be arranged alternately; and

an average of the impurity concentration in the first region and the impurity concentration in the second region adjoining the first region may decrease from the side of the second electrode to the side of the first electrode.

A higher voltage may be applied to the second electrode than that applied to the first electrode; and

an impurity concentration of the diffusion layer may linearly decrease from the side of the second electrode to the side of the first electrode.

The diffusion layer may be formed so as to include an inversion layer having an inverted conductivity type, which is produced in a region in the first semiconductor region that contacts the insulating layer, when a reverse-direction voltage is applied to the first electrode and the second electrode;

a higher voltage may be applied to the second electrode than that applied to the first electrode; and

an impurity concentration of the diffusion layer may linearly decrease from the side of the second electrode to the side of the first electrode.

The diffusion layer may comprise a first region in which an impurity concentration is constant, and a second region in which an impurity concentration is higher than that in the first region;

the first region and the second region may be arranged alternately;

an average of the impurity concentration in the first region and the impurity concentration in the second region adjoining the first region may decrease from the side of the second electrode to the side of the first electrode;

a higher voltage may be applied to the second electrode than that applied to the first electrode; and

an impurity concentration of the diffusion layer may linearly decrease from the side of the second electrode to the side of the first electrode.

The diffusion layer may be formed so as to include an inversion layer having an inverted conductivity type, which is produced in a region in the first semiconductor region that contacts the insulating layer, when a reverse-direction voltage is applied to the first electrode and the second electrode;

the diffusion layer may comprise a first region in which an impurity concentration is constant, and a second region in which an impurity concentration is higher than that in the first region;

the first region and the second region may be arranged alternately;

an average of the impurity concentration in the first region and the impurity concentration in the second region adjoining the first region may decrease from the side of the second electrode to the side of the first electrode;

a higher voltage may be applied to the second electrode than that applied to the first electrode; and

an impurity concentration of the diffusion layer may linearly decrease from the side of the second electrode to the side of the first electrode.

The semiconductor device may further comprise an insulating film formed at least on a surface of the first semiconductor region that contacts the diffusion layer; and

the diffusion layer may be sandwiched between the insulating film and the insulating layer.

The diffusion layer may be formed so as to include an inversion layer having an inverted conductivity type, which is produced in a region in the first semiconductor region that contacts the insulating layer, when a reverse-direction voltage is applied to the first electrode and the second electrode;

the semiconductor device may further comprise an insulating film formed at least on a surface of the first semiconductor region that contacts the diffusion layer; and

the diffusion layer may be sandwiched between the insulating film and the insulating layer.

To achieve the above object, a semiconductor device according to a second aspect of the present invention comprises:

a semiconductor base comprising: a first semiconductor region having a first conductivity type; a second semiconductor region having a second conductivity type formed in a surface region of the first semiconductor region; a trench formed so as to extend from a surface region of the second semiconductor region into the first semiconductor region; an insulating layer formed on a surface of the trench, and a field plate formed so as to fill the trench via the insulating layer;

a first electrode formed on the second semiconductor region which is formed in one principal surface of the semiconductor base, such that the first electrode contacts the field plate; and

a second electrode formed on the other principal surface of the semiconductor base,

wherein the semiconductor device further comprises a diffusion layer in which an impurity having the first conductivity type is diffused such that a carrier concentration in an inversion layer which is produced in the first semiconductor region that contacts the insulating layer in a direction connecting the first electrode and the second electrode, when a reverse-direction voltage is applied to the first electrode and the second electrode, is substantially uniform in the direction connecting the first electrode and the second electrode.

The diffusion layer may be formed so as to include an inversion layer having an inverted conductivity type, which is produced in a region in the first semiconductor region that contacts the insulating layer, when a reverse-direction voltage is applied to the first electrode and the second electrode.

The diffusion layer may comprise a first region in which an impurity concentration is constant, and a second region in which an impurity concentration is higher than that in the first region;

the first region and the second region may be arranged alternately; and

an average of the impurity concentration in the first region and the impurity concentration in the second region adjoining the first region may decrease from the side of the second electrode to the side of the first electrode.

The diffusion layer may be formed so as to include an inversion layer having an inverted conductivity type, which is produced in a region in the first semiconductor region that contacts the insulating layer, when a reverse-direction voltage is applied to the first electrode and the second electrode;

the diffusion layer may comprise a first region in which an impurity concentration is constant, and a second region in which an impurity concentration is higher than that in the first region;

the first region and the second region may be arranged alternately; and

an average of the impurity concentration in the first region and the impurity concentration in the second region adjoining the first region may decrease from the side of the second electrode to the side of the first electrode.

A higher voltage may be applied to the second electrode than that applied to the first electrode; and

an impurity concentration of the diffusion layer may linearly decrease from the side of the second electrode to the side of the first electrode.

The diffusion layer may be formed so as to include an inversion layer having an inverted conductivity type, which is produced in a region in the first semiconductor region that contacts the insulating layer, when a reverse-direction voltage is applied to the first electrode and the second electrode;

a higher voltage may be applied to the second electrode than that applied to the first electrode; and

an impurity concentration of the diffusion layer may linearly decrease from the side of the second electrode to the side of the first electrode.

The diffusion layer may comprise a first region in which an impurity concentration is constant, and a second region in which an impurity concentration is higher than that in the first region;

the first region and the second region may be arranged alternately;

an average of the impurity concentration in the first region and the impurity concentration in the second region adjoining the first region may decrease from the side of the second electrode to the side of the first electrode;

a higher voltage may be applied to the second electrode than that applied to the first electrode; and

an impurity concentration of the diffusion layer may linearly decrease from the side of the second electrode to the side of the first electrode.

The diffusion layer may be formed so as to include an inversion layer having an inverted conductivity type, which is produced in a region in the first semiconductor region that contacts the insulating layer, when a reverse-direction voltage is applied to the first electrode and the second electrode;

the diffusion layer may comprise a first region in which an impurity concentration is constant, and a second region in which an impurity concentration is higher than that in the first region;

the first region and the second region may be arranged alternately;

an average of the impurity concentration in the first region and the impurity concentration in the second region adjoining the first region may decrease from the side of the second electrode to the side of the first electrode;

a higher voltage may be applied to the second electrode than that applied to the first electrode; and

an impurity concentration of the diffusion layer may linearly decrease from the side of the second electrode to the side of the first electrode.

The semiconductor device may further comprise an insulating film formed at least on a surface of the first semiconductor region that contacts the diffusion layer; and

the diffusion layer may be sandwiched between the insulating film and the insulating layer.

The diffusion layer may be formed so as to include an inversion layer having an inverted conductivity type, which is produced in a region in the first semiconductor region that contacts the insulating layer, when a reverse-direction voltage is applied to the first electrode and the second electrode;

the semiconductor device may further comprise an insulating film formed at least on a surface of the first semiconductor region that contacts the diffusion layer; and

the diffusion layer may be sandwiched between the insulating film and the insulating layer.

### BRIEF DESCRIPTION OF THE DRAWINGS

These objects and other objects and advantages of the present invention will become more apparent upon reading of the following detailed description and the accompanying drawings in which:

FIG. 1 is a cross-sectional diagram showing an example of a structure of a semiconductor device according to an embodiment of the present invention;

FIG. 2 is a cross-sectional diagram exemplarily showing a state of the semiconductor device shown in FIG. 1, where the electric potential of a drain electrode is set higher than the electric potential of a source electrode;

FIG. 3 is a cross-sectional diagram showing a modified example of the semiconductor device according to the embodiment of the present invention;

FIG. 4 is a cross-sectional diagram showing another modified example of the semiconductor device according to the embodiment of the present invention;

FIG. 5 is a cross-sectional diagram showing a conventional semiconductor device having a trench structure; and

FIG. 6 is a cross-sectional diagram exemplarily showing a state of the semiconductor device shown in FIG. 5, where the electric potential of a drain electrode is set higher than the electric potential of a source electrode.

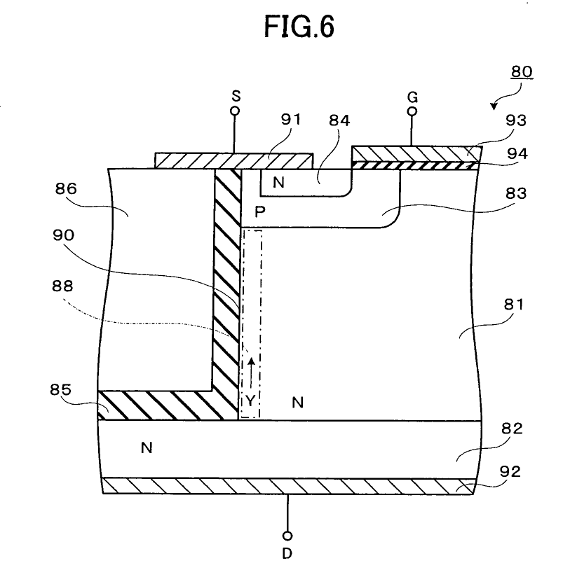

### DETAILED DESCRIPTION OF THE PREFERRED EMBODIMENT

A semiconductor device according to an embodiment of the present invention will be explained with reference to the drawings. The following embodiment will be explained by employing a vertical MOSFET (Metal Oxide Semiconductor Field Effect Transistor) as an example of the semiconductor device.

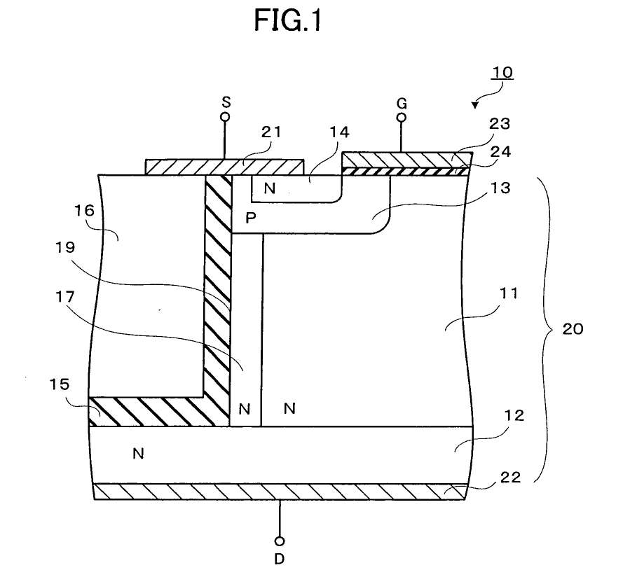

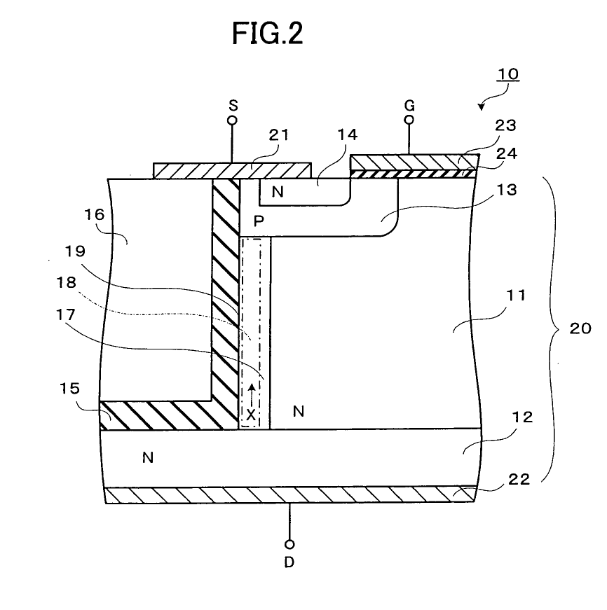

The semiconductor device 10 according to an embodiment of the present invention is shown in FIG. 1 and FIG. 2. FIG. 2 is a cross-sectional diagram exemplarily showing the semiconductor device 10 in a state where the electric potential of a drain electrode 22 is set higher than the electric potential of the source electrode 21.

As shown in FIG. 1, the semiconductor device 10 comprises a semiconductor base 20, a source electrode 21, a drain electrode 22, a gate electrode 23, and a gate insulating film 24. The semiconductor base 20 comprises an N type semiconductor region 11, an N type drain region 12, a P type base region 13, an N type source region 14, an insulating layer 15, a field plate 16, an N type diffusion layer 17, and a trench 19.

The N type semiconductor region 11 is formed of a semiconductor region of N type (first conductivity type) in which phosphorus, arsenic, etc. are diffused. The N type semiconductor region 11 is formed on the upper surface of the N type drain region 12 by epitaxial growth. The N type semiconductor region 11 is formed to have, for example, a thickness of about 70 μm and an impurity concentration of about 1×10¹³ to 1×10¹⁶ cm⁻³.

The N type drain region 12 is formed of a semiconductor region of N type (first conductivity type) in which phosphorus, arsenic, etc. are diffused. The N type drain region 12 is formed on the lower surface of the N type semiconductor region 11. The N type drain region 12 is formed to have a thickness of, for example, about 400 μm. It is preferable that the N type impurity concentration of the N type drain region 12 be higher than the N type impurity concentration of the N type semiconductor region 11, and for example, about 1×10¹⁹ cm⁻³.

The P type base region 13 is formed of a P type semiconductor region in which P type impurities (second conductivity type) such as boron, etc. are diffused. The P type base region 13 is formed in the surface region of the N type semiconductor region 11. The gate electrode 23 is formed on a region included in the surface region of the P type base region 13, that is sandwiched between the N type semiconductor region 11 and the N type source region 14. Note that the gate insulating film 24 is formed between the gate electrode 23 and the P type base region 13. The P type base region 13 is formed to have a thickness of, for example, about 3 μm. The P type impurity concentration of the P type base region 13 is, for example, about 5×10¹⁷ cm⁻³.

The N type source region 14 is formed of a semiconductor region of N type (first conductivity type) in which phosphorous, arsenic, etc. are diffused. The N type source region 14 is formed in the surface region of the P type base region 13. The source electrode 21 is formed on the N type source region 14. The N type source region 14 is formed to have a thickness of, for example, about 0.5 μm. The N type impurity concentration of the N type source region 14 is, for example, about 1×10²⁰ cm⁻³.

The trench 19 is dug in a surface of the semiconductor base 20 on the side of the source electrode 21. The trench 19 penetrates the P type base region 13. The trench 19 reaches the surface of the N type drain region 12. The insulating layer 15 is formed of silicon dioxide (SiO₂). The insulating layer 15 is formed on the surface (inner wall) of the trench 19.

The field plate 16 is formed of a conductor, for example, metal. Alternatively, the field plate 16 may be formed of polysilicon given conductivity with impurities such as phosphorus, arsenic, boron, or the like, diffused therein. The field plate 16 is formed to fill the trench 19 via the insulating film 15. The field plate 16 contacts the source electrode 21. Accordingly, a voltage applied to the source electrode 21 propagates to the field plate 16.

The N type diffusion layer 17 is formed of an N type semiconductor region in which N type impurities (first conductivity type) such as phosphorus, arsenic, etc. are diffused. The N type diffusion layer 17 is formed so as to be sandwiched between the insulating layer 15 and the N type semiconductor region 11. As shown in FIG. 1, the N type diffusion layer 17 is formed so as to contact both the P type base region 13 and the N type drain region 12. Alternatively, the N type diffusion layer 17 may be formed so as to be apart from one or both of the P type base region 13 and the N type drain region 12. It is preferred that the thickness of the N type diffusion layer 17 (the thickness being the distance from the interface between the N type diffusion layer 17 and the insulating layer 15 to the interface between the N type diffusion layer 17 and the N type semiconductor region 11) be larger than the thickness of a P type inversion layer 18 shown in FIG. 2, which is produced when the electric potential of the drain electrode 22 with respect to the electric potential of the source electrode 21 becomes higher than a predetermined level (the thickness of the P type inversion layer 18 being the distance from the interface between the P type inversion layer 18 and the insulating layer 15 to the interface between the P type inversion layer 18 and the N type diffusion layer 17, or the distance from the interface between the P type inversion layer 18 and the insulating layer 15 to the interface between the P type inversion layer 18 and the N type semiconductor region 11). Further, it is preferred that the N type diffusion layer 17 be formed so as to include the P type inversion layer 18.

The N type impurity concentration of the N type diffusion layer 17 linearly increases from the side of the source electrode 21 (the side of the P type base region 13) to the side of the drain electrode 22 (the side of the N type drain region 12). That is, a concentration gradient of the N type impurities exists in the N type diffusion layer 17. The N type impurity concentration of a part of the N type diffusion layer 17 that is closest to the P type base region 13 is, for example, about 1×10¹⁶ cm⁻³. The N type impurity concentration of a part of the N type diffusion layer 17 that is closest to the N type drain region 12 is, for example, about 1×10¹⁸ cm⁻³.

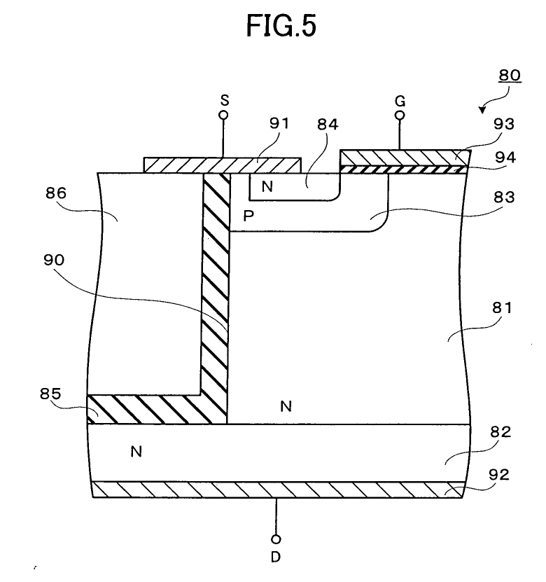

As shown in FIG. 2, the P type inversion layer 18 is a layer which is produced by the N type diffusion layer 17 becoming P type (being inverted) when the voltage near the interface between the insulating layer 15 and the N type diffusion layer 17 becomes higher than a predetermined level. As described above, it is preferred that the N type diffusion layer 17 be formed to be thicker than the P type inversion layer 18, and to include the P type inversion layer 18. In the conventional semiconductor device 80 (FIG. 5), the carrier (hole) concentration of the P type inversion layer 88 (corresponding to the P type inversion layer 18 of FIG. 2) substantially linearly decreases from the side of the drain electrode 92 (corresponding to the drain electrode 22 of FIG. 2) to the side of the source electrode 91 (corresponding to the source electrode 21 of FIG. 22). As compared to this, in the semiconductor device 10 (FIG. 2) according to the embodiment of the present invention, the impurity concentration of the N type diffusion layer 17 has a concentration gradient which decreases substantially linearly from the side of the drain electrode 22 to the side of the source electrode 21. Further, this concentration gradient is set almost equal to the gradient of the carrier concentration of the P type inversion layer 18. Accordingly, when the electric potential of the drain electrode 22 becomes higher than the electric potential of the source electrode 21, the semiconductor device 10 is kept from being inverted to P type. As a result, the carrier concentration of the P type inversion layer 18 becomes substantially uniform when it is observed vertically (in the direction that connects the drain electrode 22 and the source electrode 21).

The source electrode 21 is formed of a metal multilayered film or the like made of, for example, aluminum (Al), etc. As shown in FIG. 1, the source electrode 21 is formed on the N type source region 14, the insulating layer 15, and the field plate 16 which are formed in one principal surface (upper surface) of the semiconductor base 20.

The drain electrode 22 is formed of a metal multilayered film or the like made of, for example, titanium-nickel (Ti—Ni), etc. As shown in FIG. 1, the drain electrode 22 is formed on the lower surface of the N type drain region 12, which constitutes the other principal surface (lower surface) of the semiconductor base 20 opposite to the side of the source electrode 21.

The gate electrode 23 is formed of, for example, polysilicon or the like. The gate electrode 23 is formed on the P type base region 13 formed in the upper surface of the semiconductor base 20 via gate insulator layer 24. When a voltage is applied to the gate electrode 23, the inside of the P type base region 13 under the gate electrode 23 is inverted to N type to form a channel, through which a forward-direction current flows between the source electrode 21 and the drain electrode 22.

The semiconductor device 10 having this structure can achieve a higher voltage withstand characteristic than achieved by the conventional semiconductor device 80 having no N type diffusion layer 17. For example, when a predetermined reverse-direction voltage (a voltage at which the drain electrode 22 is higher than the source electrode 21 by a predetermined degree) is applied to the semiconductor device 10 of the present embodiment, the concentration of the carriers (holes) in the P type inversion layer 18 becomes substantially uniform in the vertical direction. This is because the N type diffusion layer 17 has a concentration gradient in its N type impurity concentration as described above. When a leak current flows in the P type inversion layer 18 in the direction of the arrow X shown in FIG. 2, the P type inversion layer 18 behaves as if it were a resistive field plate. As a result, a favorable depletion layer (for example, a complete depletion) is produced in the N type semiconductor region 11. This is because the resistance in the P type inversion layer 18 becomes substantially uniform since the carrier concentration in the P type inversion layer 18 is substantially uniform. Owing to this mechanism, the voltage withstand characteristic in the semiconductor region 10 is increased.

In this manner, the semiconductor device 10 according to the present embodiment achieves a favorable voltage withstand characteristic by being provided with the N type diffusion layer 17 having an impurity concentration gradient. Accordingly, unlike the methods conventionally employed for increasing the voltage withstand characteristic, such as forming the insulating layer 15 thick, forming the N type semiconductor region 11 thick, etc., it is possible to provide a semiconductor device having a favorable voltage withstand characteristic, without changing the size of the semiconductor device.

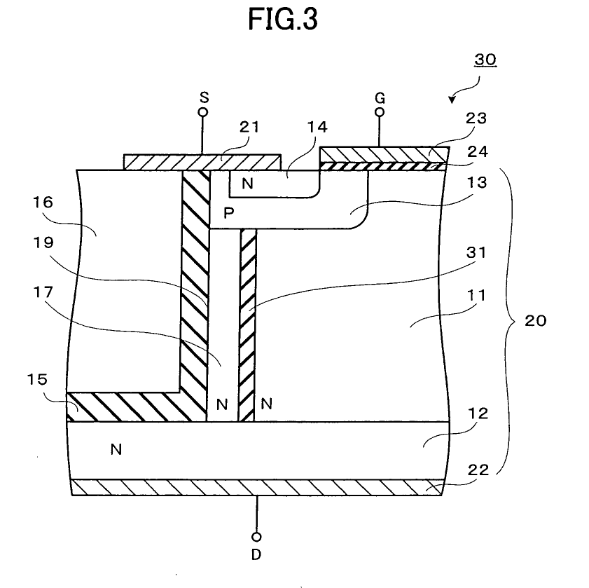

The present invention is not limited to the above-described embodiment, but can be modified and applied in various manners. For example, in the above-described embodiment, a structure in which the N type diffusion layer 17 is formed so as to be sandwiched between the N type semiconductor region 11 and the insulating layer 15, has been employed as an example. However, various other structures are conceivable. For example, as in a semiconductor device 30 shown in FIG. 3, an insulating film 31 may be formed on the interface between the N type semiconductor region 11 and the N type diffusion layer 17. In other words, the insulating film 31 may be formed such that the N type diffusion layer 17 is sandwiched between the insulating film 31 and the insulating layer 15. The following advantages exist in employing this structure. That is, in a thermal treatment process succeeding the formation of the N type diffusion layer 17, it is possible to prevent the impurities diffused in the N type diffusion layer 17 from being diffused into the N type semiconductor region 11. Thus, it is possible to prevent the impurity concentration of the N type diffusion layer 17 from decreasing.

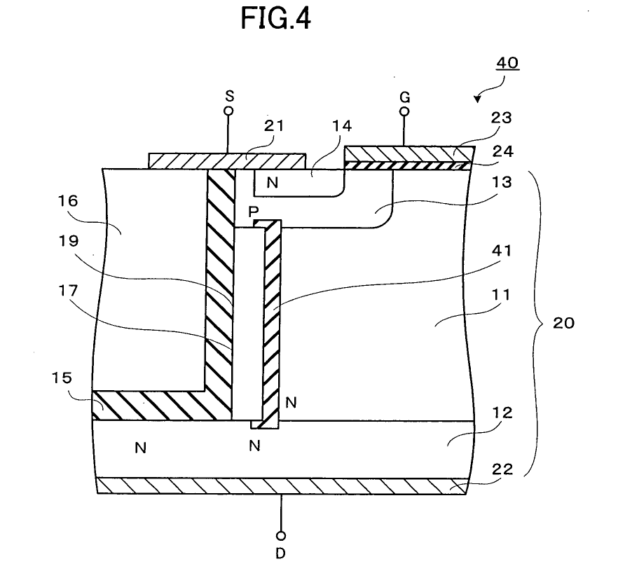

Further, as in a semiconductor device 40 shown in FIG. 4, an insulating film 41 may be formed not only on the surface of the N type semiconductor region 11 that contacts the N type diffusion layer 17, but also on the surfaces of the N type diffusion layer 17 that contact other regions. That is, the insulating film 41 may be formed, for example, on the surface of the N type diffusion layer 17 that contacts the P type base region 13, and on the surface of the N type diffusion layer 17 that contacts the N type drain region 12. However, it is preferred that the insulating film 41 be formed such that, for example, the upper surface of the N type diffusion layer 17 (interface to the P type base region 13) and the lower surface thereof (interface to the N type drain region 12) are partly exposed. This is because if the N type diffusion layer 17 is completely covered by the insulating film 41 and the insulating layer 15, no leak current having a required volume will flow, which is no good.

The above-described embodiment is an example for making the carrier concentration of the P type inversion layer 18 uniform. In the above-described embodiment, the concentration gradient in the impurity concentration of the N type diffusion layer 17 linearly decreases from the drain electrode 22 to the source electrode 21. However, the concentration gradient needs not be linear. For example, the impurity concentration of the N type diffusion layer 17 may be decreased stepwise from the side of the drain electrode 22 to the side of the source electrode 21. Further, two kinds of regions, namely a first region in which the impurity concentration is constant and a second region in which the impurity concentration is higher than that in the first region may be alternately formed in the N type diffusion layer 17. In this case, the impurity concentration in the second region is formed so as to be lower as the region is closer to the side of the source electrode 21. That is, the impurity concentration of the N type diffusion layer 17 repeats being high and low from the drain electrode 22 to the source electrode 21. However, it should be noted that the average of the constant impurity concentration in the first region and the higher impurity concentration in the adjoining second region decreases substantially linearly from the drain electrode 22 to the source electrode 21.

Further, in the above-described embodiment, the explanation has been made by employing a vertical MOSFET as an example. However, the present invention is not limited to this, but can be applied to a diode, a Zener diode, a transistor, an IGBT (Insulated Gate Bipolar Transistor), a thyristor, etc. Furthermore, the present invention can be applied to a semiconductor device having a trench-gate structure, and an IC (Integrated Circuit) having a semiconductor device.

In the above-described embodiment, it has been explained that the first conductivity type is N type, and the second conductivity type is P type. However, the first conductivity type may be P type, and the second conductivity type may be N type. Furthermore, the thickness and the impurity concentrations indicated in the embodiment are mere examples, and may thus be changed as needed.

According to the present invention, it is possible to provide a semiconductor device having a favorable voltage withstand characteristic without changing the thickness of the insulating layer, by forming a diffusion layer having an impurity concentration gradient.

Various embodiments and changes may be made thereunto without departing from the broad spirit and scope of the invention. The above-described embodiment is intended to illustrate the present invention, not to limit the scope of the present invention. The scope of the present invention is shown by the attached claims rather than the embodiment. Various modifications made within the meaning of an equivalent of the claims of the invention and within the claims are to be regarded to be in the scope of the present invention.

This application is based on Japanese Patent Application No. 2005-199758 filed on Jul. 8, 2005 and including specification, claims, drawings and summary. The disclosure of the above Japanese Patent Application is incorporated herein by reference in its entirety.

What is claimed is:

1. A semiconductor device, comprising:
a semiconductor base comprising: a first semiconductor region having a first conductivity type; a second semiconductor region having a second conductivity type formed in a surface region of said first semiconductor region; a trench formed so as to extend from a surface region of said second semiconductor region into said first semiconductor region; an insulating layer formed on a surface of said trench, and a field plate formed so as to fill said trench via said insulating layer;
a first electrode formed on said second semiconductor region which is formed in one principal surface of said semiconductor base, such that said first electrode contacts said field plate; and
a second electrode formed on the other principal surface of said semiconductor base,
wherein said semiconductor device further comprises a diffusion layer in which an impurity is diffused with a concentration gradient running from a side of said first electrode to a side of said second electrode, in said first semiconductor region contacting said insulating layer in a direction connecting said first electrode and said second electrode.

2. The semiconductor device according to claim 1,
wherein said diffusion layer is formed so as to include an inversion layer having an inverted conductivity type, which is produced in a region in said first semiconductor region that contacts said insulating layer, when a reverse-direction voltage is applied to said first electrode and said second electrode.

3. The semiconductor device according to claim 1,
wherein:
said diffusion layer comprises a first region in which an impurity concentration is constant, and a second region in which an impurity concentration is higher than that in said first region;
said first region and said second region are arranged alternately; and
an average of the impurity concentration in said first region and the impurity concentration in said second region adjoining said first region decreases from the side of said second electrode to the side of said first electrode.

4. The semiconductor device according to claim 1,
wherein:
said diffusion layer is formed so as to include an inversion layer having an inverted conductivity type, which is produced in a region in said first semiconductor region that contacts said insulating layer, when a reverse-direction voltage is applied to said first electrode and said second electrode;
said diffusion layer comprises a first region in which an impurity concentration is constant, and a second region in which an impurity concentration is higher than that in said first region;
said first region and said second region are arranged alternately; and
an average of the impurity concentration in said first region and the impurity concentration in said second region adjoining said first region decreases from the side of said second electrode to the side of said first electrode.

5. The semiconductor device according to claim 1,
wherein:
a higher voltage is applied to said second electrode than that applied to said first electrode; and
an impurity concentration of said diffusion layer linearly decreases from the side of said second electrode to the side of said first electrode.

6. The semiconductor device according to claim 1,
wherein:
said diffusion layer is formed so as to include an inversion layer having an inverted conductivity type, which is produced in a region in said first semiconductor region that contacts said insulating layer, when a reverse-direction voltage is applied to said first electrode and said second electrode;
a higher voltage is applied to said second electrode than that applied to said first electrode; and
an impurity concentration of said diffusion layer linearly decreases from the side of said second electrode to the side of said first electrode.

7. The semiconductor device according to claim 1,
wherein:
said diffusion layer comprises a first region in which an impurity concentration is constant, and a second region in which an impurity concentration is higher than that in said first region;
said first region and said second region are arranged alternately;
an average of the impurity concentration in said first region and the impurity concentration in said second region adjoining said first region decreases from the side of said second electrode to the side of said first electrode;
a higher voltage is applied to said second electrode than that applied to said first electrode; and
an impurity concentration of said diffusion layer linearly decreases from the side of said second electrode to the side of said first electrode.

8. The semiconductor device according to claim 1,
wherein:
said diffusion layer is formed so as to include an inversion layer having an inverted conductivity type, which is produced in a region in said first semiconductor region that contacts said insulating layer, when a reverse-direction voltage is applied to said first electrode and said second electrode;
said diffusion layer comprises a first region in which an impurity concentration is constant, and a second region in which an impurity concentration is higher than that in said first region;
said first region and said second region are arranged alternately;
an average of the impurity concentration in said first region and the impurity concentration in said second region adjoining said first region decreases from the side of said second electrode to the side of said first electrode;
a higher voltage is applied to said second electrode than that applied to said first electrode; and
an impurity concentration of said diffusion layer linearly decreases from the side of said second electrode to the side of said first electrode.

9. The semiconductor device according to claim 1,
wherein:
said semiconductor device further comprises an insulating film formed at least on a surface of said first semiconductor region that contacts said diffusion layer; and
said diffusion layer is sandwiched between said insulating film and said insulating layer.

10. The semiconductor device according to claim 1,
wherein:
said diffusion layer is formed so as to include an inversion layer having an inverted conductivity type, which is produced in a region in said first semiconductor region that contacts said insulating layer, when a reverse-direction voltage is applied to said first electrode and said second electrode;
said semiconductor device further comprises an insulating film formed at least on a surface of said first semiconductor region that contacts said diffusion layer; and
said diffusion layer is sandwiched between said insulating film and said insulating layer.

11. A semiconductor device, comprising:
a semiconductor base comprising: a first semiconductor region having a first conductivity type; a second semiconductor region having a second conductivity type formed in a surface region of said first semiconductor region; a trench formed so as to extend from a surface region of said second semiconductor region into said first semiconductor region; an insulating layer formed on a surface of said trench, and a field plate formed so as to fill said trench via said insulating layer;
a first electrode formed on said second semiconductor region which is formed in one principal surface of said semiconductor base, such that said first electrode contacts said field plate; and
a second electrode formed on the other principal surface of said semiconductor base,
wherein said semiconductor device further comprises a diffusion layer in which an impurity having the first conductivity type is diffused such that a carrier concentration in an inversion layer which is produced in said first semiconductor region that contacts said insulating layer in a direction connecting said first electrode and said second electrode, when a reverse-direction voltage is applied to said first electrode and said second electrode, is substantially uniform in the direction connecting said first electrode and said second electrode.

12. The semiconductor device according to claim 11,
wherein said diffusion layer is formed so as to include an inversion layer having an inverted conductivity type, which is produced in a region in said first semiconductor region that contacts said insulating layer, when a reverse-direction voltage is applied to said first electrode and said second electrode.

13. The semiconductor device according to claim 11,
wherein:
said diffusion layer comprises a first region in which an impurity concentration is constant, and a second region in which an impurity concentration is higher than that in said first region;
said first region and said second region are arranged alternately; and
an average of the impurity concentration in said first region and the impurity concentration in said second region adjoining said first region decreases from the side of said second electrode to the side of said first electrode.

14. The semiconductor device according to claim 11,
wherein:
said diffusion layer is formed so as to include an inversion layer having an inverted conductivity type, which is produced in a region in said first semiconductor region that contacts said insulating layer, when a reverse-direction voltage is applied to said first electrode and said second electrode;
said diffusion layer comprises a first region in which an impurity concentration is constant, and a second region in which an impurity concentration is higher than that in said first region;
said first region and said second region are arranged alternately; and
an average of the impurity concentration in said first region and the impurity concentration in said second region adjoining said first region decreases from the side of said second electrode to the side of said first electrode.

15. The semiconductor device according to claim 11,
wherein:
a higher voltage is applied to said second electrode than that applied to said first electrode; and
an impurity concentration of said diffusion layer linearly decreases from the side of said second electrode to the side of said first electrode.

16. The semiconductor device according to claim 11,
wherein:
said diffusion layer is formed so as to include an inversion layer having an inverted conductivity type, which is produced in a region in said first semiconductor region that contacts said insulating layer, when a reverse-direction voltage is applied to said first electrode and said second electrode;
a higher voltage is applied to said second electrode than that applied to said first electrode; and
an impurity concentration of said diffusion layer linearly decreases from the side of said second electrode to the side of said first electrode.

17. The semiconductor device according to claim 11,
wherein:
said diffusion layer comprises a first region in which an impurity concentration is constant, and a second region in which an impurity concentration is higher than that in said first region;
said first region and said second region are arranged alternately;
an average of the impurity concentration in said first region and the impurity concentration in said second region adjoining said first region decreases from the side of said second electrode to the side of said first electrode;
a higher voltage is applied to said second electrode than that applied to said first electrode; and
an impurity concentration of said diffusion layer linearly decreases from the side of said second electrode to the side of said first electrode.

18. The semiconductor device according to claim 11,
wherein:
said diffusion layer is formed so as to include an inversion layer having an inverted conductivity type, which is produced in a region in said first semiconductor region that contacts said insulating layer, when a reverse-direction voltage is applied to said first electrode and said second electrode;
said diffusion layer comprises a first region in which an impurity concentration is constant, and a second region in which an impurity concentration is higher than that in said first region;
said first region and said second region are arranged alternately;
an average of the impurity concentration in said first region and the impurity concentration in said second region adjoining said first region decreases from the side of said second electrode to the side of said first electrode;
a higher voltage is applied to said second electrode than that applied to said first electrode; and
an impurity concentration of said diffusion layer linearly decreases from the side of said second electrode to the side of said first electrode.

19. The semiconductor device according to claim 11,
wherein:
said semiconductor device further comprises an insulating film formed at least on a surface of said first semiconductor region that contacts said diffusion layer; and
said diffusion layer is sandwiched between said insulating film and said insulating layer.

20. The semiconductor device according to claim 11,
wherein:
said diffusion layer is formed so as to include an inversion layer having an inverted conductivity type, which is produced in a region in said first semiconductor region that contacts said insulating layer, when a reverse-direction voltage is applied to said first electrode and said second electrode;
said semiconductor device further comprises an insulating film formed at least on a surface of said first semiconductor region that contacts said diffusion layer; and
said diffusion layer is sandwiched between said insulating film and said insulating layer.
